(19) United States
(12) Patent Application Publication
(10) Pub. No.: US 2015/0200343 A1
(43) Pub. Date: Jul. 16, 2015

(54) SUBSTRATE FOR LIGHT EMITTING DIODE AND METHOD OF MANUFACTURING THE SAME AND LIGHT SOURCE APPARATUS INCLUDING THE SUBSTRATE

(71) Applicant: RESEARCH & BUSINESS FOUNDATION SUNGKYUNKWAN UNIVERSITY, Suwon-si (KR)

(72) Inventors: Su-jeong SUH, Suwon-si (KR); Hwa-sun PARK, Suwon-si (KR); Jung-kab PARK, Haman-gun (KR); Young-lae CHO, Suwon-si (KR); Tae-yoo KIM, Suwon-si (KR); Jae-hoon SHIN, Suwon-si (KR); Jin-ha SHIN, Siheung-si (KR); Jung-woo LEE, Suwon-si (KR); Hwa-jin SON, Dalseong-gun (KR); Jung-ho PARK, Seoul (KR)

(73) Assignee: RESEARCH & BUSINESS FOUNDATION SUNGKYUNKWAN UNIVERSITY, Suwon-si (KR)

(21) Appl. No.: 14/595,915

(22) Filed: Jan. 13, 2015

(30) Foreign Application Priority Data
Jan. 14, 2014 (KR) 10-2014-0004343

(51) Int. Cl. H01L 33/64; H05K 1/05; H05K 1/02; H01L 33/62

(52) U.S. Cl. CPC H01L 33/647; H01L 33/62; H05K 1/05; H05K 1/0284

(57) ABSTRACT

A substrate for a light emitting diode (LED) and a method of manufacturing the substrate for the LED are provided. The substrate for the LED includes a conductive substrate which includes an upper surface including a first flat surface and a second flat surface stepped from the first flat surface, an insulating layer formed on the second flat surface, and an electrode layer spaced apart from the first flat surface and disposed on the insulating layer.

### CROSS-REFERENCE TO RELATED APPLICATION

This application claims the benefit under 35 USC 119(a) of Korean Patent Application No. 10-2014-0004343, filed on Jan. 14, 2014, the entire disclosure of which is incorporated herein by reference for all purposes.

### BACKGROUND

1. Field of the Invention

The present invention relates to a substrate for a light emitting diode (LED), a method of manufacturing the substrate and a light source apparatus including the substrate, and more specifically, to a substrate for an LED that has excellent heat dissipation characteristics, a method of manufacturing the substrate and a light source apparatus including the substrate.

2. Discussion of Related Art

Recently, the relative importance of light emitting diodes (LEDs) among various light sources is continuously growing in aspects of environmental regulations and efficiency both domestically and globally. This is because LEDs have higher efficiency than conventional light sources and may generate light of high luminance.

LEDs generate light by combination of electrons and holes, and heat is inevitably generated in addition to the light when the electrons and holes combine. LEDs emit only about 20% of supplied energy as light energy and the remaining about 80% as heat energy. In addition, a high output LED generates heat at high temperatures of about 100° C. or more due to high power consumption. Therefore, there is a problem in that high output LEDs generate more heat than general LEDs.

When heat from an LED is not dissipated, there is a risk of damage to elements in the LED, a shortened lifetime, and reduced operating efficiency. In particular, heat dissipation is more important in an ultraviolet (UV) LED because the UV LED generates a lot of heat due to its high power consumption.

In order to resolve this problem, a device structure capable of easily dissipating heat from an LED is required, and a related light source apparatus is as follows.

FIG. 1 is a diagram illustrating a conventional light source apparatus.

Referring to FIG. 1, the conventional light source apparatus may include an LED, a ceramic substrate, two electrode layers and a via hole connecting the two electrode layers. The electrode layers and the LED may be connected by a conductive wire.

The via hole formed on the ceramic substrate is plated with copper, and heat from the LED is dissipated through the via hole to the outside of the light source apparatus. However, the conventional light source apparatus has had a problem in that efficiency of the heat dissipation is low because the heat may be dissipated only through the via hole.

### SUMMARY OF THE INVENTION

The present invention is directed to a substrate for a light emitting diode (LED) that has excellent heat dissipation characteristics and a method of manufacturing the substrate.

Also, the present invention is directed to a light source apparatus including the substrate for the LED that has excellent heat dissipation characteristics.

One aspect of the present invention provides a substrate for an LED including a conductive substrate which includes an upper surface including a first flat surface and a second flat surface stepped from the first flat surface, an insulating layer formed on the second flat surface, and an electrode layer spaced apart from the first flat surface and disposed on the insulating layer.

In an embodiment, the conductive substrate may have a length in a first direction and a width in a second direction perpendicular to the first direction, the first flat surface may extend along a first edge extending in the first direction among upper edges of the conductive substrate, the second flat surface may extend along a second edge of the conductive substrate facing the first edge, and a width of the first flat surface in the second direction may be smaller than a width of the second flat surface in the second direction.

In an embodiment, the second flat surface may be disposed at a lower portion than the first flat surface.

In an embodiment, the substrate may be formed of one or more materials selected from the group consisting of copper, aluminum, a copper alloy and an aluminum alloy.

In an embodiment, the insulating layer may be formed of an organic or inorganic insulation material.

In an embodiment, the insulating layer may have an area greater than the electrode layer.

One aspect of the present invention provides a light source apparatus including a conductive substrate which includes an upper surface including a first flat surface and a second flat surface stepped from the first flat surface, an insulating layer formed on the second flat surface, an electrode layer spaced apart from the first surface and disposed on the insulating layer, and an LED including a first electrode and a second electrode electrically connected to the electrode layer and the first flat surface, respectively.

In an embodiment, the substrate may be formed of one or more materials selected from the group consisting of copper, aluminum, a copper alloy and an aluminum alloy.

In an embodiment, the first electrode may be electrically connected to the electrode layer by a wire bonding, and the second electrode may be electrically connected to the first flat surface of the substrate by a soldering bonding.

In an embodiment, the insulating layer may be formed of an organic or inorganic insulation material.

Another aspect of the present invention provides a method of manufacturing a substrate for an LED including forming an etch mask which covers a first region in an upper surface of a substrate including the first region and a second region adjacent to the first region, etching the second region to a desired depth through an etching process using the etch mask and forming a first flat surface corresponding to the first region and a second flat surface stepped from the first flat surface and formed through the etching process in the upper surface of the substrate, forming an insulating layer on the second flat surface, and forming an electrode layer on the insulating layer.

In an embodiment, the method further including forming a protective layer which covers a lower surface and side surfaces of the substrate on which the etch mask is formed, and the forming of the protective layer may be performed after the etch mask is formed and before the etching process is performed.

In an embodiment, the insulating layer may be formed by curing a thermosetting or photocurable resin composition deposited within a space formed by the protective layer, a stepped surface of the substrate and the first flat surface.

In an embodiment, the electrode layer may be formed on the insulating layer through an electroless plating process or a printing process.

In an embodiment, the method further including removing the etch mask and the protective layer after the electrode layer is formed.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a diagram illustrating a conventional light source apparatus;

FIG. 2 is a lateral view illustrating a light source apparatus according to an embodiment of the present invention;

FIG. 3 is a plan view illustrating the light source apparatus according to the embodiment of the present invention;

FIG. 4 is a diagram illustrating a substrate according to an embodiment of the present invention;

FIG. 5 is a conceptual diagram illustrating a method of manufacturing a substrate for a light emitting diode (LED) according to an embodiment of the present invention;

FIG. 6 is a flow chart illustrating the method of manufacturing the substrate for the LED according to the embodiment of the present invention; and

FIG. 7 is a graph comparing respective reflectivity characteristics according to wavebands of aluminum, gold and silver.

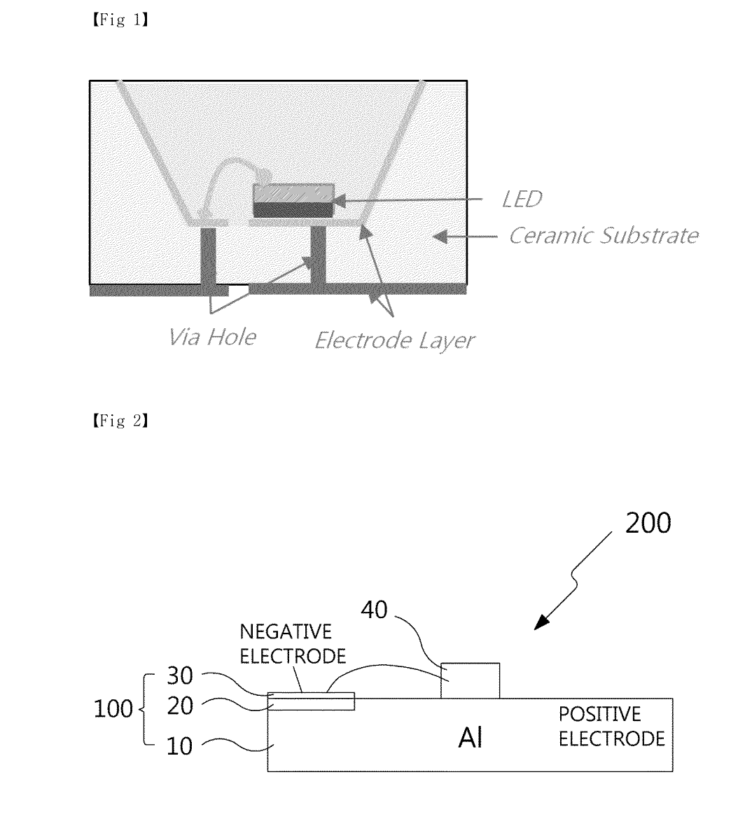

### DETAILED DESCRIPTION OF EMBODIMENTS

The present invention may be variously modified and may have a variety of exemplary embodiments, and thus particular embodiments will be exemplified in drawings and will be explained in detail in the description. However, these are not intended to limit the present invention to a particular form of implementation, and it will be understood that all modifications, equivalents and substitutes are included in the spirit and scope of the present invention.

Hereinafter, a preferred exemplary embodiment according to the present invention is described in detail referring to the accompanying drawings. In the drawings, like numerals refers to like elements.

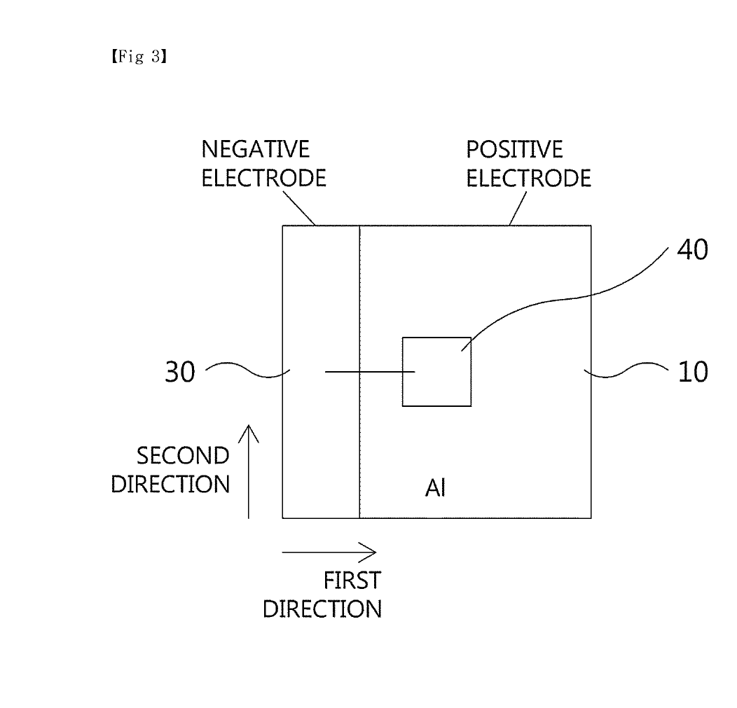

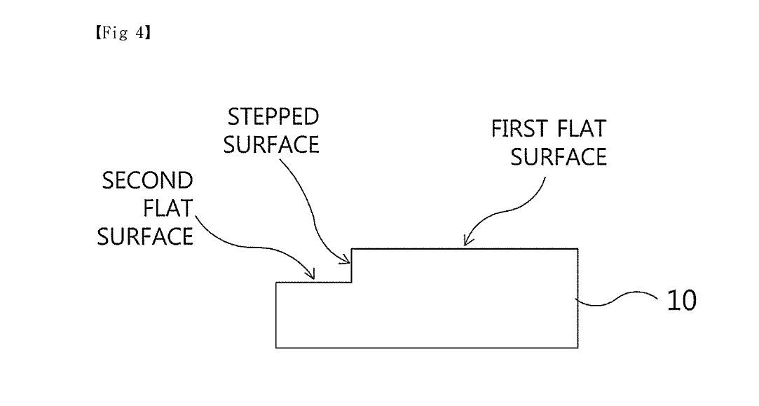

FIG. 2 is a lateral view illustrating a light source apparatus according to an embodiment of the present invention, FIG. 3 is a plan view illustrating the light source apparatus according to the embodiment of the present invention, and FIG. 4 is a diagram illustrating a substrate according to an embodiment of the present invention.

Referring to FIGS. 2 to 4, a light source apparatus 200 according to the embodiment of the present invention may include a light emitting diode (LED) 40 and a substrate 100 for the LED. In addition, the substrate 100 for the LED according to the embodiment of the present invention may include a substrate 10, an insulating layer 20 and an electrode layer 30.

The substrate 10 may be conductive and may include an upper surface including a first flat surface and a second flat surface stepped from the first flat surface. The LED 40 which will be described below may be disposed on the first flat surface, and the insulating layer 20 and the electrode layer 30 may be disposed on the second flat surface. For example, the second flat surface may be disposed at a lower portion than the first flat surface because the insulating layer 20 and the electrode layer 30 are formed on the second flat surface.

The substrate 10 may have a length in a first direction and a width in a second direction perpendicular to the first direction. The first flat surface may extend along a first edge extending in the first direction among upper edges of the substrate 10, and the second flat surface may extend along a second edge of the substrate 10 facing the first edge, and a width of the first flat surface in the second direction may be lower than a width of the second flat surface in the second direction.

For example, the substrate 10 may be formed of one or more materials selected from the group consisting of copper, aluminum, copper alloys and aluminum alloys. Although gold (Au) and silver (Ag), etc., which have excellent heat dissipation characteristics, may be used for the substrate 10, it is preferable to use aluminum (Al), an aluminum alloy, copper (Cu) or a copper alloy, etc. in consideration of the economic cost.

The insulating layer 20 may be formed on the second flat surface as illustrated above. The insulating layer 20 may electrically insulate the electrode layer 30 and the conductive substrate 10. For example, the insulating layer 20 may be formed of an organic or inorganic insulation material. For example, the insulating layer 20 may be a thermosetting or photocurable resin composition. The insulating layer 20 may be formed by curing an insulation material deposited within a space formed in the substrate 10, which will be described in detail below.

The electrode layer 30 may be disposed on the insulating layer 20. This serves to electrically separate the substrate 10 and the electrode layer 30. For example, an area of the insulating layer 20 may be greater than that of the electrode layer 30 such that the substrate 10 and the electrode layer 30 may be spaced apart and insulated.

The LED 40 may include a first electrode and a second electrode, and the first electrode may be negative and the second electrode may be positive. The electrode layer 30 may be electrically connected to the first electrode of the LED 40, and the first flat surface of the substrate 10 may be electrically connected to the second electrode of the LED 40. For example, the first electrode of the LED 40 may be electrically connected to the electrode layer 30 by a wire bonding, and gold (Au), aluminum (Al), or copper (Cu), etc. may be used for the wire bonding. In addition, the second electrode of the LED 40 may be electrically connected to the first flat surface of the substrate 10 by a soldering bonding.

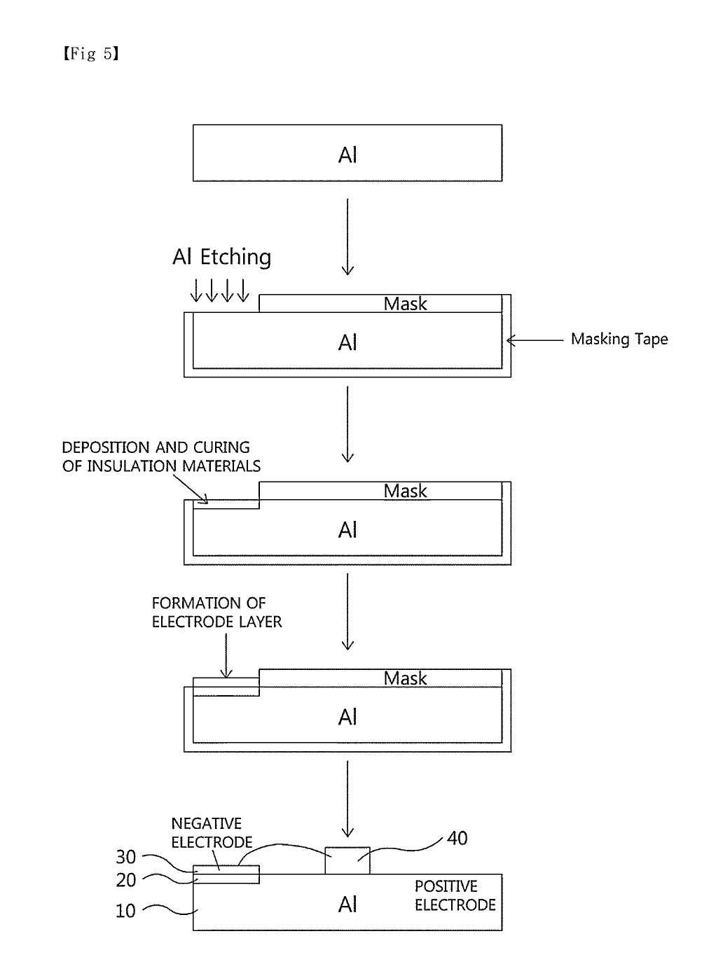

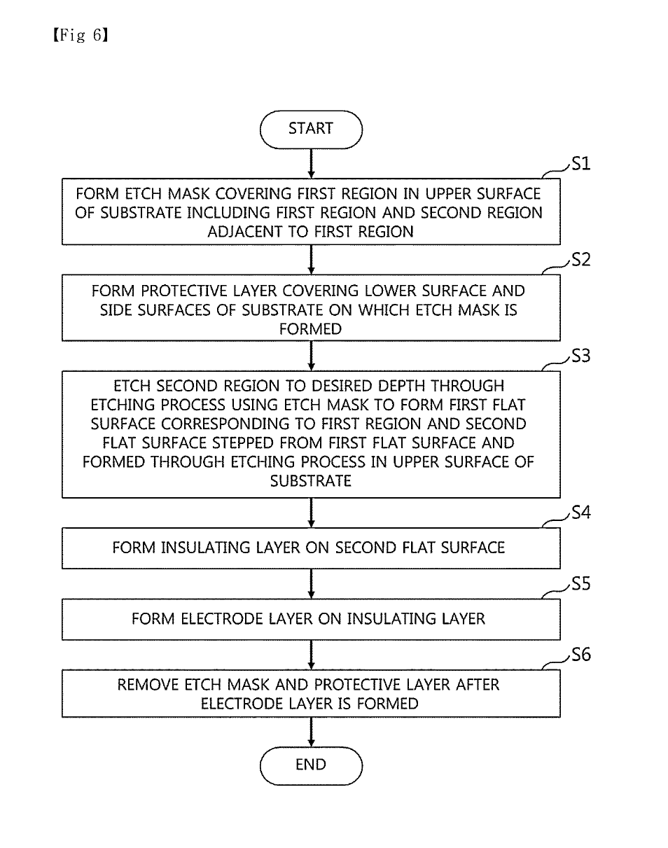

FIG. 5 is a conceptual diagram illustrating a method of manufacturing a substrate for an LED according to an embodiment of the present invention, and FIG. 6 is a flow chart illustrating the method of manufacturing the substrate for the LED according to the embodiment of the present invention.

Referring to FIGS. 5 and 6, an etch mask covering a first region is formed in an upper surface of a substrate 10 including the first region and a second region adjacent to the first region (51). For example, a dry film may be used for the etch mask.

After the etch mask is formed on the upper surface of the substrate 10, a protective layer covering both a lower surface and side surfaces of the substrate 10 is formed (S2). For example, a dry film which is a masking tape may be used for the protective layer.

After the etch mask and the protective layer are formed on the upper surface, the lower surface and the side surfaces of the substrate 10, the second region of the substrate 10 is etched to a desired depth through an etching process using the etch mask to form a first flat surface corresponding to the first region and a second flat surface formed through the etching process and stepped from the first flat surface in the upper surface of the substrate 10 (S3). The second flat surface may be formed at a lower portion than the first flat surface because the second flat surface is etched to the desired depth.

The etching process may be performed through a wet etch or dry etch method. For example, when the etching process is performed through the wet etch method, one or more of hydrochloric acid, sulfuric acid, nitric acid and sodium hydroxide (NaOH) may be used as an etchant. For example, a solution including phosphoric acid, nitric acid, acetic acid and DI water may be used as an etchant when aluminum or an aluminum alloy is used for the substrate 10, and a solution including nitric acid, hydrogen peroxide, and iron chloride or hydrochloric acid may be used as an etchant when copper or a copper alloy is used for the substrate 10.

When the etching process is finished, residue on the substrate 10 may be removed by washing the etchant with DI water. By removing the residue, adhesion between the substrate 10 and an insulating layer 20 formed on the second flat surface of the substrate 10 may be improved.

After the first flat surface and the second flat surface are formed on the upper surface of the substrate 10 through the etching process, an insulating layer is formed on the second flat surface (S4).

The insulating layer 20 may be formed by curing a thermosetting or photocurable resin composition deposited within a space formed by the protective layer, a stepped surface of the substrate 10 and the second flat surface. For example, it is preferable to use a thermosetting resin composition maintained that remains unmelted at high temperatures for the insulating layer 20 because the LED 40 emits high-temperature heat.

After the insulating layer 20 is formed, an electrode layer 30 is formed on the insulating layer 20 (S3). The electrode layer 30 may be formed on the insulating layer 20 through a deposition process such as an electroless plating process, vacuum sputtering, etc., or through a printing process. The formed electrode layer 30 may have a predetermined thickness, and the thickness may be changed arbitrarily. For example, gold (Au), silver (Ag), aluminum (Al), and copper (Cu), etc. may be used for the electrode layer 30, and various metals having conductive characteristics may be used for the electrode layer 30.

After the electrode layer 30 is formed, the etch mask and the protective layer formed on the substrate 10 are removed (S6). A substrate 100 for the LED according to the embodiment of the present invention may be manufactured through the above processes.

After the mask and the protective layer are removed, the LED 40 is disposed on the first flat surface of the substrate 100 to be spaced apart from the electrode layer 30. Then, the electrode layer 30 may be electrically connected to the first electrode of the LED 40 and the first flat surface of the substrate 10 may be electrically connected to the second electrode of the LED 40 in order to manufacture the light source apparatus 200 according to the embodiment of the present invention. For example, an ultraviolet (UV) LED may be used for the LED 40. After the LED 40 is disposed on the substrate 10, lens formation and phosphor deposition may be sequentially performed.

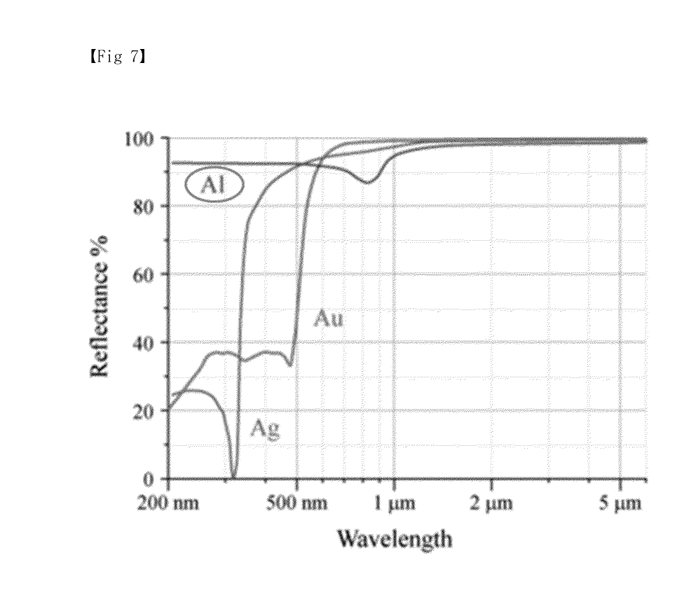

FIG. 7 is a graph comparing respective reflectivity characteristics according to wavebands of aluminum, gold and silver.

Referring to FIG. 7, it may be seen that the reflectivity of aluminum in a UV waveband between about 260 nm and 380 nm is about 90% or more which is significantly higher than those of gold and silver.

Therefore, when aluminum is used for a substrate 100 for the LED, and a light source apparatus 200 is manufactured using the substrate 100 for the LED 40 which emits UV wavelengths, higher reflectivity and more efficient heat dissipation characteristics may be achieved than in a light source apparatus 200 in which gold or silver is used for the substrate 100.

The present invention may increase an area of heat dissipation of an LED, thereby efficiently dissipating heat from the LED.

In addition, the present invention may prevent damage to a light source apparatus due to heat from the LED, thereby extending a lifetime of the light source apparatus and maintaining performance of the light source apparatus.

Heat from an UV LED may be efficiently dissipated when aluminum, which is excellent in reflectivity in a UV band, is used for a substrate for the LED.

An insulating layer may be formed without a bonding process, thereby reducing overall processing time and cost.

An insulating layer may be formed to be parallel with a substrate, thereby improving mechanical strength of a substrate itself even when a force is exerted on the substrate in a perpendicular direction.

Although the present invention has been explained with reference to the above exemplary embodiments, it will be apparent to those skilled in the art that various modifications can be made to the above-described exemplary embodiments of the present invention without departing from the spirit or scope of the invention. Here, the essential technical scope of the present invention is disclosed in the appended claims, and it is intended that the present invention cover all such modifications provided they come within the scope of the claims and their equivalents.

What is claimed is:

1. A substrate for a light emitting diode comprising:
a conductive substrate including an upper surface which includes a first flat surface and a second flat surface stepped from the first flat surface;
an insulating layer formed on the second flat surface; and
an electrode layer spaced apart from the first flat surface and disposed on the insulating layer.

2. The substrate of claim 1, wherein
the conductive substrate has a length in a first direction and a width in a second direction perpendicular to the first direction,
the first flat surface extends along a first edge extending in the first direction among upper edges of the conductive substrate,
the second flat surface extends along a second edge of the conductive substrate facing the first edge, and
a width of the first flat surface in the second direction is smaller than a width of the second flat surface in the second direction.

3. The substrate of claim 1, wherein the second flat surface is disposed at a lower portion than the first flat surface.

4. The substrate of claim 1, wherein the substrate is formed of one or more of materials selected from the group consisting of copper, aluminum, a copper alloy and an aluminum alloy.

5. The substrate of claim 1, wherein the insulating layer is formed of an organic or inorganic insulation material.

6. The substrate of claim 1, wherein the insulating layer has an area greater than the electrode layer.

7. A light source device comprising:
a conductive substrate including an upper surface which includes a first flat surface and a second flat surface stepped from the first flat surface;
an insulating layer formed on the second flat surface;
an electrode layer spaced apart from the first flat surface and disposed on the insulating layer; and
a light emitting diode including a first electrode and a second electrode electrically connected to the electrode layer and the first flat surface, respectively.

8. The light source device of claim 7, wherein the substrate is formed of one or more materials selected from the group consisting of copper, aluminum, a copper alloy and an aluminum alloy.

9. The light source apparatus of claim 7, wherein
the first electrode is electrically connected to the electrode layer by a wire bonding, and
the second electrode is electrically connected to the first flat surface of the substrate by a soldering bonding.

10. The light source device of claim 7, wherein the insulating layer is formed of an organic or inorganic insulation material.

11. A method of manufacturing a substrate for a light emitting diode comprising:
forming an etch mask which covers a first region in an upper surface of a substrate including the first region and a second region adjacent to the first region;
etching the second region to a desired depth through an etching process using the etch mask, and forming a first flat surface corresponding to the first region and a second flat surface formed through the etching process and stepped from the first flat surface in the upper surface of the substrate;
forming an insulating layer on the second flat surface; and
forming an electrode layer on the insulating layer.

12. The method of claim 11, further comprising:
forming a protective layer which covers a lower surface and side surfaces of the substrate on which the etch mask is formed,
wherein the forming of the protective layer is performed after the etch mask is formed and before the etching process is performed.

13. The method of claim 12, wherein the insulating layer is formed by curing a thermosetting or photocurable resin composition deposited within a space formed by the protective layer, a stepped surface of the substrate and the first flat surface.

14. The method of claim 13, wherein the electrode layer is formed on the insulating layer through an electroless plating process or a printing process.

15. The method of claim 14, further comprising removing the etch mask and the protective layer after the electrode layer is formed.
